(19) United States
(12) Patent Application Publication
(10) Pub. No.: US 2025/0390133 A1
(43) Pub. Date: Dec. 25, 2025

(54) SEMICONDUCTOR INTEGRATED CIRCUIT AND ELECTRONIC APPARATUS

(71) Applicant: Kioxia Corporation, Tokyo (JP)

(72) Inventor: Yoshikazu NAGASHIMA, Yokohama Kanagawa (JP)

(21) Appl. No.: 19/074,990

(22) Filed: Mar. 10, 2025

(30) Foreign Application Priority Data
Jun. 21, 2024 (JP) 2024-100663

(51) Int. Cl. G05F 3/26; G11C 16/04; G11C 16/30

(52) U.S. Cl. CPC G05F 3/262; G11C 16/30; G11C 16/0483

(57) ABSTRACT

A semiconductor integrated circuit includes a smoothing circuit, first to third circuits, and a control circuit. The first circuit is configured to cause a first current to flow to the smoothing circuit, to output a first voltage to a first terminal. The second circuit is configured to cause a second current to flow to the smoothing circuit, to output the first voltage to the first terminal. The second current is greater than the first current. The third circuit is configured to cause a third current corresponding to the first current to flow to a second terminal. The control circuit is configured to cause, during a first time period, the first and second currents to flow to the smoothing circuit, then during a second time period, the first current to flow to the smoothing circuit, and then during a third time period, the third current to flow to the second terminal.

### CROSS-REFERENCE TO RELATED APPLICATION

This application is based upon and claims the benefit of priority from Japanese Patent Application No. 2024-100663, filed Jun. 21, 2024, the entire contents of which are incorporated herein by reference.

### FIELD

Embodiments described herein relate generally to a semiconductor integrated circuit and an electronic apparatus.

### BACKGROUND

In a semiconductor integrated circuit, a band gap reference (BGR) circuit is used as a circuit that generates a reference voltage. The BGR circuit requires low temperature dependence and high voltage stability to generate a reference voltage to be used in the semiconductor integrated circuit.

In mobile-oriented communication equipment or the like, high-speed start-up of a power supply circuit, which may include the BGR circuit, is desirable. Also, to improve communication quality, the BGR circuit in the power supply circuit is desirable to have a high power supply rejection ratio (PSRR).

In general, to stabilize a power supply voltage generated by the power supply circuit, a low pass filter (LPF) is disposed at an output stage. However, since a rise of an output voltage (that is, the power supply voltage) of the power supply circuit is delayed due to a capacitance component in the LPF, it is difficult to implement high-speed start-up of the power supply circuit.

### BRIEF DESCRIPTION OF THE DRAWINGS

FIG. 1 is a circuit diagram illustrating an example of a semiconductor integrated circuit according to a first embodiment.

FIG. 2 is a flowchart illustrating an example of a control operation performed in the semiconductor integrated circuit according to the first embodiment.

FIG. 3 is a timing chart illustrating an example of the control operation performed in the semiconductor integrated circuit according to the first embodiment.

FIG. 4 is a circuit diagram illustrating a first state during the control operation performed in the semiconductor integrated circuit according to the first embodiment.

FIG. 5 is a circuit diagram illustrating a second state during the control operation performed in the semiconductor integrated circuit according to the first embodiment.

FIG. 6 is a circuit diagram illustrating a third state during the control operation performed in the semiconductor integrated circuit according to the first embodiment.

FIG. 7 is a circuit diagram illustrating a fourth state during the control operation performed in the semiconductor integrated circuit according to the first embodiment.

FIG. 8 is a flowchart illustrating a control operation of a semiconductor integrated circuit according to a modification of the first embodiment.

FIG. 9 is a timing chart illustrating an example of the control operation performed in the semiconductor integrated circuit according to the modification example of the first embodiment.

FIG. 10 is a block diagram illustrating a configuration of an electronic apparatus according to a second embodiment.

### DETAILED DESCRIPTION

Embodiments provide a semiconductor integrated circuit and an electronic apparatus that achieve both high quality and high-speed start-up.

In general, according to an embodiment, a semiconductor integrated circuit includes a smoothing circuit, a first circuit, a second circuit, a third circuit, and a control circuit. The first circuit is electrically connected to the smoothing circuit and a first output terminal and configured to cause a first current to flow to the smoothing circuit, thereby outputting a first voltage to the first output terminal. The second circuit is electrically connected to the smoothing circuit and the first output terminal and configured to cause a second current to flow to the smoothing circuit, thereby outputting the first voltage to the first output terminal. The second current is greater than the first current. The third circuit is electrically connected to a second output terminal and configured cause a third current corresponding to the first current to flow to the second output terminal. The control circuit is configured to cause, during a first time period, the first current and the second current to flow to a capacitor of the smoothing circuit, during a second time period subsequent to the first time period, the first current, but not the second current, to flow to the capacitor, the second time period being greater than the first time period, and during a third time period subsequent to the second time period, the third current to flow to the second output terminal.

### First Embodiment

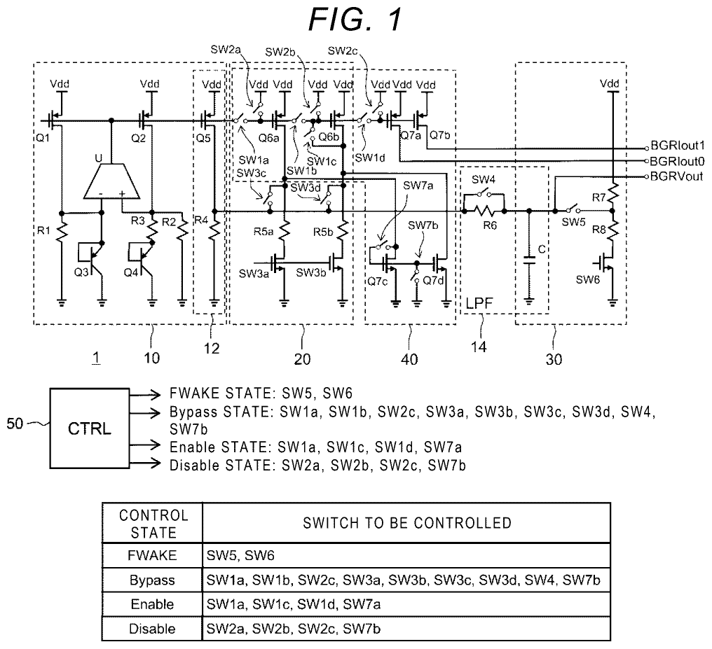

FIG. 1 shows an example of a semiconductor integrated circuit according to a first embodiment. A semiconductor integrated circuit 1 as a BGR circuit has a voltage source circuit 10, a scaling circuit 20, a low pass filter (LPF) 14, a voltage division circuit 30, a current mirror circuit 40, and a control circuit 50. The voltage source circuit 10 includes an output circuit 12. The scaling circuit 20 and the current mirror circuit 40 share part of circuit components. The LPF 14 and the voltage division circuit 30 share part of circuit components.

The voltage source circuit 10 (may be referred to as “first circuit”) generates a reference voltage. In the example illustrated in FIG. 1, the voltage source circuit 10 has MOSFETs Q1, Q2, and Q5, an operational amplifier U, transistors Q3 and Q4, and resistors R1 to R4. The MOSFETs Q1 and Q2 have sources, each of which is connected to a power supply wiring Vdd, and gates connected to each other. The MOSFET Q1 has a drain connected to a ground wiring via the resistor R1. The MOSFET Q2 has a drain connected to the ground wiring via the resistor R2. The power supply wiring Vdd is a wiring to which a voltage serving as a power supply voltage when the semiconductor integrated circuit 1 operates is supplied. The ground wiring is a wiring to which a ground voltage when the semiconductor integrated circuit 1 operates is supplied.

The operational amplifier U has an output connected to the gates of the MOSFETs Q1 and Q2, an inverting input connected to the drain of the MOSFET Q1, and a non-inverting input connected to the drain of the MOSFET Q2. The transistor Q3 has a base, an emitter connected to the inverting input of the operational amplifier U and the base thereof, and a collector connected to the ground wiring. The transistor Q4 has a base, an emitter connected to the base thereof, and a collector connected to the ground wiring. The emitter and the base of the transistor Q4 are connected to the non-inverting input of the operational amplifier U via the resistor R3.

The operational amplifier U negatively feeds back a difference between a drain voltage of the MOSFET Q1 and a drain voltage of the MOSFET Q2 to the gate of the MOSFET Q1 and the gate of the MOSFET Q2. With this, the drain voltage of the MOSFET Q1 and the drain voltage of the MOSFET Q2 are kept equal to each other. That is, the operational amplifier U can stabilize an output voltage.

The MOSFET Q5 has a source connected to the power supply wiring Vdd, a gate connected to the gate of each of the MOSFET Q1 and Q2, and a drain connected to the ground wiring via the resistor R4. The MOSFETs Q1, Q2, and Q5 form a current mirror. The current mirror and the operational amplifier U jointly act as a constant current circuit that keeps drain currents of the MOSFETs Q1, Q2, and Q5 constant. The MOSFET Q5 and the resistor R4 form the output circuit 12 in the voltage source circuit 10.

In FIG. 1, the drain voltage of the MOSFET Q1 and the drain voltage of the MOSFET Q2 become equal to each other and are stabilized by the operation of the current mirror including the MOSFETs Q1, Q2, and Q5 and the operational amplifier U. Here, an emitter-collector voltage of the transistor Q4 has a negative coefficient with respect to temperature, and as a result a current flowing through the resistor R2 also has a negative coefficient with respect to temperature. Meanwhile, the resistor R3 generally has a positive coefficient with respect to temperature. Accordingly, a temperature dependence of the current flowing through the resistor R2 and a temperature dependence of the current flowing through the resistor R3 are offset with each other, and a drain current of the MOSFET Q5 in the output circuit 12 becomes a current independent of temperature. That is, the transistor Q3 and Q4 and the resistors R1 to R3 act as a temperature compensation circuit.

In this way, the voltage source circuit 10 can output a stabilized voltage with no or little temperature dependence.

The scaling circuit 20 (may be referred to as “fourth circuit”) scales up an output current of the voltage source circuit 10. That is, the scaling circuit 20 increases the output current of the voltage source circuit 10. In the example illustrated in FIG. 1, the scaling circuit 20 has MOSFETs Q6a and Q6b, switches SW1a to SW1c, SW2a, SW2b, and SW3a to SW3d, and resistors R5a and R5b. The MOSFET Q6a has a source connected to the power supply wiring Vdd, a gate connected to the switches SW1a and SW2a, and a drain connected to the ground wiring via the resistor R5a and the switch SW3a. Similarly, the MOSFET Q6b has a source connected to the power supply wiring Vdd, a gate connected to the switches SW1b, SW1c, and SW2b, and a drain connected to the ground wiring via the resistor R5b and the switch SW3b. The switches SW1a to SW1c, SW2a, SW2b, SW3c, and SW3d may be implemented by, for example, transfer gates (may be referred to as “transmission gates”). The switches SW3a and SW3b may be implemented by, for example, switching elements such as MOSFETs.

The gate of the MOSFET Q6a is connected to a gate of the MOSFET Q5 of the voltage source circuit 10 (more specifically, the output circuit 12) via the switch SW1a. That is, when the switch SW1a is on, the MOSFETs Q1, Q2, Q5, and Q6a form a current mirror. The gate of the MOSFET Q6a is connected to the power supply wiring Vdd via the switch SW2a. The drain of the MOSFET Q6a is connected to the drain of the MOSFET Q5 via the switch SW3c. In addition, the drain of the MOSFET Q6a is connected to the LPF 14 including the switch SW4, via the switch SW3c.

The gate of the MOSFET Q6b is connected to the gate of the MOSFET Q5 of the voltage source circuit 10 (more specifically, the output circuit 12) via the switch SW1b and the switch SW1a. That is, when the switch SW1a and the switch SW1b are on, the MOSFETs Q1, Q2, Q5, Q6a, and Q6b form a current mirror. The gate of the MOSFET Q6b is connected to the power supply wiring Vdd via the switch SW2b. In addition, the gate of the MOSFET Q6b is connected to the drain of the MOSFET Q6b via the switch SW1c. The drain of the MOSFET Q6b is connected to the drain of the MOSFET Q5 via the switch SW3d. In addition, the drain of the MOSFET Q6b is connected to the LPF 14 including the switch SW4, via the switch SW3d.

The MOSFETS Q6a and Q6b of the scaling circuit 20 have an interconnection width greater than that of the MOSFET Q5 of the voltage source circuit 10. This means that the MOSFETs Q6a and Q6b can allow a greater current to flow than can the MOSFET Q5. That is, the scaling circuit 20 acts as a circuit that scales up the output current of the voltage source circuit 10.

The LPF 14 (smoothing circuit) smoothes a voltage (i.e., output voltage) of an output BGRVout of the semiconductor integrated circuit 1. The LPF 14 has the switch SW4, a resistor R6, and a capacitor C, and forms a so-called CR filter. The switch SW4 and the resistor R6 are connected in parallel. One end of the resistor R6 is connected to the drain of the MOSFET Q5, and the other end of the resistor R6 is connected to one end of the capacitor C. The other end of the capacitor C is connected to the ground wiring. An intersection point between the other end of the resistor R6 and the one end of the capacitor C is connected to the output BGRVout.

When the switches SW1a, SW1b, SW3a to SW3d, SW4, and SW7b are on and the switches SW1c, SW2a, and SW2b are off, the gate of each of the MOSFETs Q6a and Q6b is connected to the gate of the MOSFET Q5 of the voltage source circuit 10 (output circuit 12), and the drain of each of the MOSFETs Q6a and Q6b is respectively connected to the ground wiring via the resistors R5a and R5b. In this state, the scaling circuit 20 starts the operation, and the output of the voltage source circuit 10 and the output of the scaling circuit 20 are input to the capacitor C of the LPF 14 via the switch SW4. Such an operation serves to quickly stabilize the output voltage of the output BGRVout.

On the other hand, when the switches SW1a, SW1b, SW3a to SW3d, SW4, and SW7b are off, and the switches SW1c, SW2a, and SW2b are on, the scaling circuit 20 stops the operation. In this state, the output of the voltage source circuit 10 is input to the resistor R6 of the LPF 14 as it is.

The voltage division circuit 30 (may be referred to as “second circuit”) quickly rises the output voltage of the output BGRVout. The voltage division circuit 30 has resistors R7 and R8 connected in series, and switches SW5 and SW6. One end of the resistor R7 is connected to one end of the resistor R8. The other end of the resistor R7 is connected to the power supply wiring Vdd. The other end of the resistor R8 is connected to the ground wiring via the switch SW6. An intersection point between the resistors R7 and R8 is connected to the intersection point between the other end of the resistor R6 and the one end of the capacitor C in the LPF 14 via the switch SW5. The switches SW5 and SW6 can be turned on or off in response to a control signal from the outside.

When the switches SW5 and SW6 are on, the resistors R7 and R8 become voltage division resistors for the voltage of the power supply wiring Vdd, and a divided voltage is input to the capacitor C of the LPF 14 via the switch SW5. Such an operation serves to quickly rise the output voltage of the output BGRVout. The switches SW4 and SW5 may be implemented by, for example, transfer gates. The switch SW6 may be implemented by, for example, a switching element such as an MOSFET.

The current mirror circuit 40 (may be referred to as “third circuit”) is a current source that generates a stabilized current in cooperation with the voltage source circuit 10. The current mirror circuit 40 has MOSFETs Q6a, Q6b, and Q7a to Q7d, and switches SW1a to SW1d, SW2a to SW2c, SW7a, and SW7b. The MOSFETs Q7a and Q7b have sources each connected to the power supply wiring Vdd, and gates connected to the gate of the MOSFET Q6b of the scaling circuit 20 via the switch SW1d. The gates of the MOSFETS Q7a and Q7b are connected to the power supply wiring Vdd via the switch SW2c. The MOSFET Q7a has a drain that outputs a current via an output BGRIout0. The MOSFET Q7b has a drain that outputs a current via an output BGRIout1. The switches SW1d and SW2c may be implemented by, for example, transfer gates. The switch SW1d and the switch SW2c are controlled to be turned on and off exclusively.

The MOSFETs Q7c and Q7d have drains connected to the drain of the MOSFET Q6a and the drain of the MOSFET Q6b, respectively, gates connected to each other, and sources connected to the ground wiring. The gate of the MOSFET Q7c is connected to the drain of the MOSFET Q7c via the switch SW7a, and the gate of the MOSFET Q7d is connected to the ground wiring via the switch SW7b. The switches SW7a and SW7b may be implemented by, for example, transfer gates.

If the switches SW1a, SW1c, SW1d, and SW7a are turned on, and the switches SW2a to SW2c, and SW7b are turned off, the current mirror circuit 40 including the MOSFETs Q6a, Q6b, and Q7a to Q7d is started. That is, a current is output via the outputs BGRIout0 and BGRIout1.

As illustrated in FIG. 1, the current mirror circuit 40 of the first embodiment uses the MOSFETS Q6a and Q6b of the scaling circuit 20. That is, part of a circuit configuration required for the current mirror circuit 40 is commonly used as part of a circuit configuration of the scaling circuit 20. This contributes to reduction of a required area of the semiconductor integrated circuit 1.

The control circuit 50 generates a plurality of control signals for controlling the switches SW1a to SW1d, SW2a to SW2c, SW3a to SW3d, SW4, SW5, SW6, SW7a, and SW7b, respectively, at prescribed timings. In the semiconductor integrated circuit 1 of the first embodiment, the control circuit 50 generates four states of a control state FWAKE, a control state Bypass, a control state Enable, and a control state Disable by the plurality of control signals. The control circuit 50 is, for example, an electronic circuit including a processor or a sequencer.

In the control state FWAKE, the voltage division circuit 30 is enabled. The control circuit 50 controls the switches SW5 and SW6 to be on to generate the control state FWAKE, and starts the voltage division circuit 30. In the control state Bypass, the scaling circuit 20 is enabled. The control circuit 50 controls the switches SW1a, SW1b, SW3a to SW3d, SW4, and SW7b to be on to generate the control state Bypass, and starts the scaling circuit 20.

In the control state Enable, the current mirror circuit 40 is enabled. The control circuit 50 controls the switches SW1a, SW1c, SW1d, and SW7a to be on, to generate the control state Enable, and starts the current mirror circuit 40.

In the control state Disable, the current mirror circuit 40 is disabled. The control circuit 50 controls the switches SW2a to SW2c, and SW7b to be on and controls the switches SW1a, SW1c, SW1d, and SW7a to be off to generate the control state Disable and to disable the control state Enable, and stops the current mirror circuit 40.

Since no current is output via the outputs BGRIout0 and BGRIout1 in a state other than the control state Enable in which the current mirror circuit 40 is enabled, and the switch SW2c is controlled to the on state.

### Operation According to First Embodiment

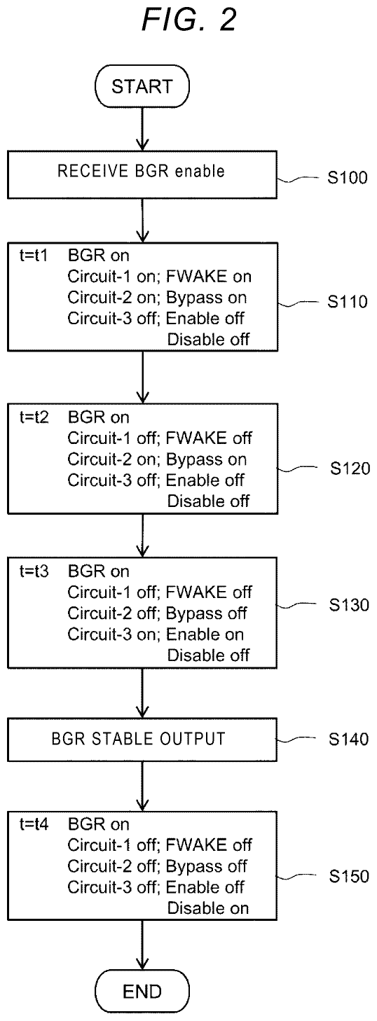

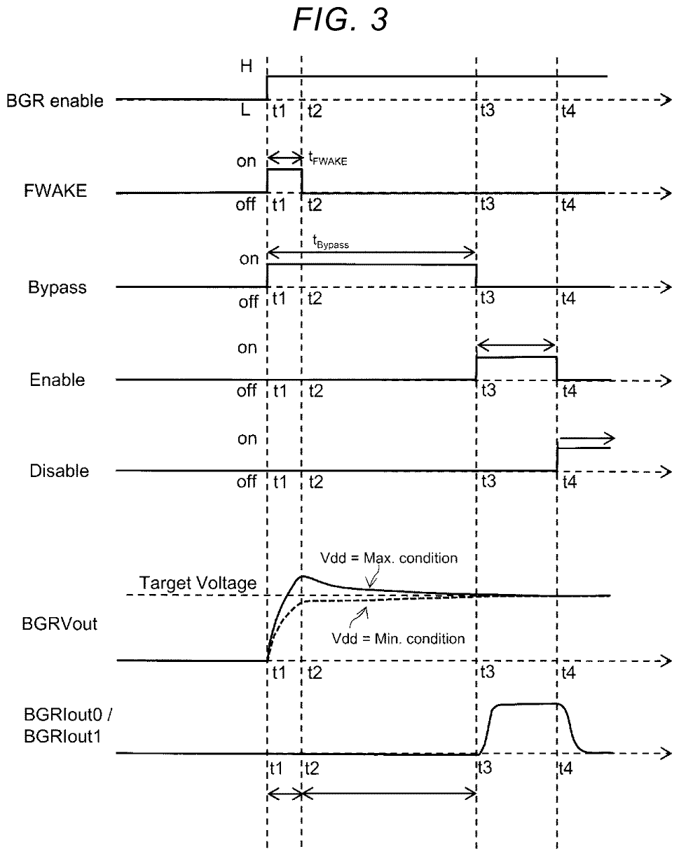

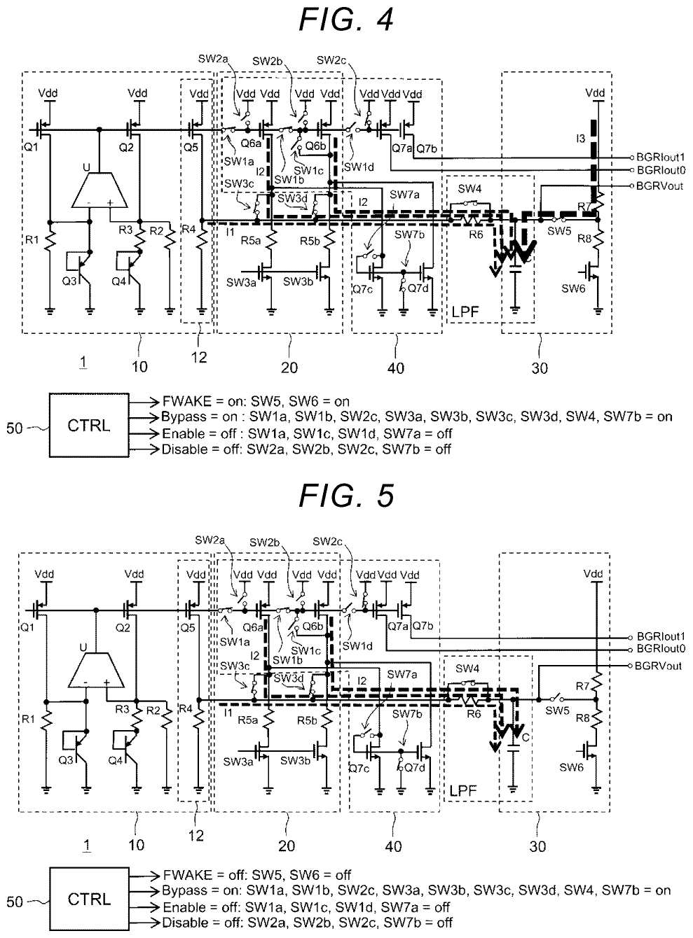

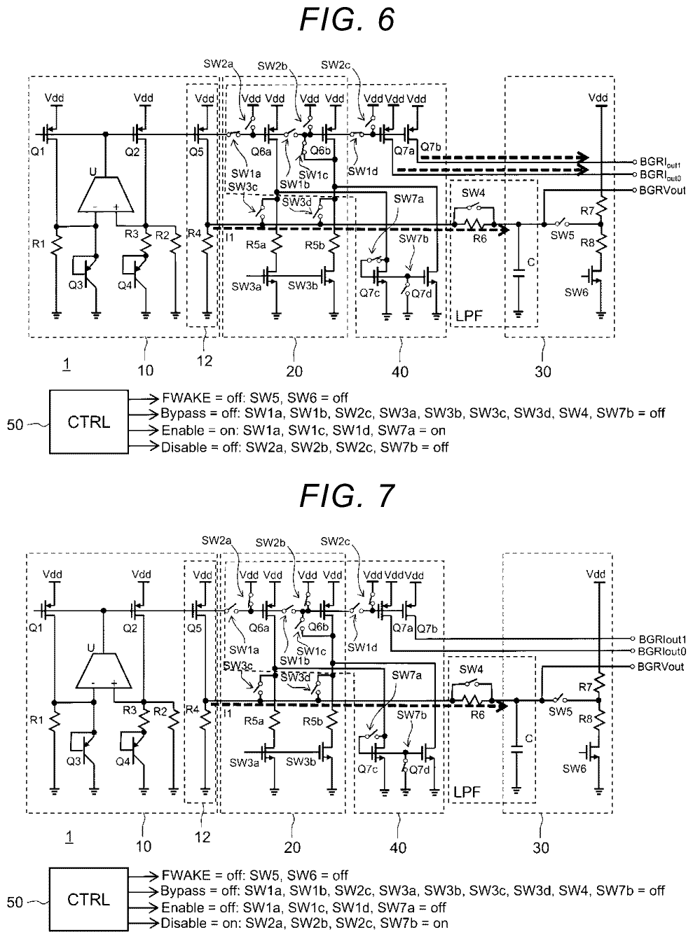

Subsequently, the operation of the semiconductor integrated circuit 1 according to the first embodiment will be described with reference to FIGS. 1 to 7. FIG. 2 is a flowchart illustrating an example of a control operation performed in the semiconductor integrated circuit according to the first embodiment. FIG. 3 is a timing chart illustrating an example of the control operation performed in the semiconductor integrated circuit according to the first embodiment. FIG. 4 is a circuit diagram illustrating a first state during the control operation performed in the semiconductor integrated circuit according to the first embodiment. FIG. 5 is a circuit diagram illustrating a second state during the control operation performed in the semiconductor integrated circuit according to the first embodiment. FIG. 6 is a circuit diagram illustrating a third state during the control operation performed in the semiconductor integrated circuit according to the first embodiment. FIG. 7 is a circuit diagram illustrating a fourth state during the control operation performed in the semiconductor integrated circuit according to the first embodiment.

As illustrated in FIGS. 2 and 3, at time t1 (i.e., the first state), upon the control circuit 50 receiving a BGR enable signal for enabling a circuit operation (S100), the control circuit 50 causes a control signal for setting each of the control state Bypass and the control state FWAKE to be at ON level and a control signal for setting the control state Enable and the control state Disable to be at Off level (S110). As a result, as illustrated in FIG. 4, the switches SW1a, SW1b, SW2c, SW3a to SW3d, SW4, and SW7b are turned on and the control state Bypass is set, the switches SW5 and SW6 are turned on and the control state FWAKE is set, the switches SW1c, SW1d, and SW7a are turned off and the control state Enable is not set, and the switches SW2a, SW2b, and SW7b are turned off and the control state Disable is not set. While the switch SW1a is turned off for not setting the control state Enable, the switch SW1a is turned on to set the control state Bypass. While the switches SW2c and SW7b are turned off for not setting the control state Disable, the switches SW2c and SW7b are turned on to set the control state Bypass. In this state, the scaling circuit 20 (Circuit-1) and the voltage division circuit 30 (Circuit-2) are started, and the current mirror circuit 40 (Circuit-3) is not started since SW2c is on.

In this case, the voltage source circuit 10 outputs a prescribed voltage, and a current I1 flows from the drain of the MOSFET Q5 toward the switch SW4. The current I1 flows toward the capacitor C of the LPF 14.

The scaling circuit 20 starts the operation when the signal for setting the control state Bypass is turned to be at ON level. In addition, since the signal for setting the control state Bypass is at ON level, the switch SW4 is turned on. In this case, a current I2 flows from the drains of the MOSFETS Q6a and Q6b toward the capacitor C of the LPF 14 via the switch SW4.

In addition, the voltage division circuit 30 starts the operation when the signal for setting the control state FWAKE is turned to be at ON level. The voltage of the power supply wiring Vdd is divided by the resistors R7 and R8. In this case, a current I3 flows from the intersection point of the one end of each of the resistors R7 and R8 toward the capacitor C of the LPF 14.

The current mirror circuit 40 is not started since the signal for setting the control state Enable is at OFF level. For this reason, no current flows via the outputs BGRIout0 and BGRIout1.

As illustrated in FIG. 3, at time t1, upon the BGR enable signal turning to an H level from a low level, the signals for setting the control state FWAKE and the control state Bypass are turned to be at ON levels. Meanwhile, the signal for setting the control state Enable remains at OFF level. The voltage source circuit 10, the scaling circuit 20, and the voltage division circuit 30 are started, and the output voltage appears at the output BGRVout. The current mirror circuit 40 is not started, and no current flows via the outputs BGRIout0 and BGRIout1. In this case, the current I2 from the scaling circuit 20 and the current I3 from the voltage division circuit 30 are added to the current I1 from the voltage source circuit 10, and the capacitor C of the LPF 14 is charged.

According to such an operation, a rise of the output voltage in a case where the scaling circuit 20 and the voltage division circuit 30 are started in parallel approaches a target voltage more quickly than a rise of the output voltage in a case where only the voltage source circuit 10 is started. AS illustrated in FIG. 3, in a case where the voltage of the power supply wiring Vdd is under a minimum condition (Min) (a broken line of FIG. 3), a rise is later than a rise in a case where the voltage of the power supply wiring Vdd is under a maximum condition (Max) (a solid line of FIG. 3), but is earlier than the rise of the output voltage in the case where only the voltage source circuit 10 is started.

Subsequently, as illustrated in FIGS. 2 and 3, at time t2 (i.e., the second state), the control circuit 50 causes a control signal for setting the control state FWAKE to be at OFF level, maintains a control signal for setting the control state Bypass to be at ON level, and maintains control signals for setting the control state Enable and the control state Disable to be at OFF levels (S120). As a result, as illustrated in FIG. 5, the switches SW5 and SW6 are turned off, the switches SW1a, SW1b, SW2c, SW3a to SW3d, SW4, and SW7b are kept on, the switches SW1c, SW1d, and SW7a are kept off, and the switches SW2a and SW2b are kept off. With this, since the voltage division circuit 30 stops the operation, the current I3 becomes zero, and a current flowing into the capacitor C of the LPF 14 decreases.

As illustrated in FIG. 3, at time t2, upon the control state FWAKE being controlled to end, the current I3 from the voltage division circuit 30 is not added to the current I1 from the voltage source circuit 10. As a result, in a case where the voltage of the power supply wiring Vdd is under the maximum condition (Max), the output voltage of the output BGRVout is turned from rising to falling. That is, the output voltage of the output BGRVout quickly rises through the control of the current I3 from the voltage division circuit 30, and the output voltage falls after exceeding the target voltage. A time t_{FWAKE} during which the control state FWAKE is set is set at a timing such that the output voltage of the output BGRVout quickly falls without exceeding the target voltage. In a case where the voltage of the power supply wiring Vdd is under the minimum condition (Min), a slope of rising of the output voltage becomes a little gentler.

Subsequently, as illustrated in FIGS. 2 and 3, at time t3 (i.e., the third state), the control circuit 50 outputs a control signal for terminating the control state Bypass, and outputs a control signal for turning on the control state Enable. The control circuit 50 maintains the control signals for setting the control state FWAKE and the control state Disable to be at OFF levels (S130). As a result, as illustrated in FIG. 6, the switches SW1b, SW2c, SW3a to SW3d, SW4, and SW7b are turned off, and the switches SW2a, SW2b, SW5, and SW6 are kept off. The switches SW1a, SW1c, SW1d, and SW7a are turned on. With this, since the scaling circuit 20 stops the operation, the current I2 becomes zero, and the current flowing into the capacitor C of the LPF 14 further decreases.

As illustrated in FIG. 3, at time t3, upon the control state Bypass being terminated and the control state Enable is controlled to be set while the control signals for setting the control state FWAKE and the control state Disable are kept at OFF levels, the drain voltage of the MOSFET Q5 of the voltage source circuit 10 is applied directly to the resistor R6 of the LPF 14, and the current flowing into the capacitor C of the LPF 14 becomes only the current I1. The output voltage of the output BGRVout that has quickly risen at time t1 is turned to decrease or gently rises at time t2, and converges to the target voltage at time t3. A time t_{Bypass} during which the control signal for setting the control state Bypass is kept at ON level is set at a timing at which the output voltage converges to the target voltage. For example, the time t_{Bypass} is set to such an extent of not exceeding 50 μs. Then, when the signal for setting the control state Enable is turned to be at ON level, the current mirror circuit 40 starts.

As illustrated in FIG. 2, at time t3, after the control circuit 50 causes the control signals for setting the control state Bypass and the control state FWAKE to be at OFF levels, the semiconductor integrated circuit 1 outputs a stable voltage (S140). In this stage, the scaling circuit 20 and the voltage division circuit 30 are not started, and the current mirror circuit 40 is started. That is, as illustrated in FIG. 3, the current mirror circuit 40 serves as a current source, and outputs a current from the outputs BGRIout0 and BGRIout1.

Subsequently, as illustrated in FIGS. 2 and 3, at time t4 (i.e., the fourth state), the control circuit 50 causes the control signal for setting the control state Enable to be at OFF level, and a control signal for setting the control state Disable to be at ON level. The control circuit 50 maintains the control signals for setting the control state FWAKE and the control state Bypass to be at OFF levels (S150). As a result, as illustrated in FIG. 7, the switches SW1a to SW1d, SW3a to SW3d, SW4, and SW7a are turned off, the switches SW2a to SW2c, and SW7b are turned on, and the switches SW5 and SW6 are kept off. With this, since the current mirror circuit 40 stops the operation, the current from the output BGRIout0 and the output BGRIout1 is stopped.

The current I1 output from the voltage source circuit 10, the current I2 output from the scaling circuit 20, and the current I3 output from the voltage division circuit 30 have the following relationship.

I1<I2<I3

(Further, the current I2 can be proportional to the current I1 because of the scaling.) That is, the voltage division circuit 30 can charge the capacitor C of the LPF 14 at a highest speed. However, since a voltage based on the current I3 output from the voltage division circuit 30 is generated by dividing a voltage on the power supply wiring Vdd, variation in a voltage value thereof is large.

On the other hand, since the current I2 output from the scaling circuit 20 is smaller than the current I3 output from the voltage division circuit 30, a charging speed of the capacitor C of the LPF 14 is not as fast as that of the voltage division circuit 30. However, since the output voltage of the scaling circuit 20 is obtained by scaling up the current I1 output from the voltage source circuit 10, a voltage value thereof is stable.

In the semiconductor integrated circuit 1 according to the first embodiment, to quickly rise the output voltage of the output BGRVout when the voltage source circuit 10 is started, both the output of the scaling circuit 20 and the output of the voltage division circuit 30 are added to the output of the voltage source circuit 10 in an initial stage (i.e., a time period of logical AND of both of the time t_{FWAKE} and the time t_{Bypass} being high levels). On the other hand, since a value of the current I3 output from the voltage division circuit 30 is relatively large, there is a possibility that the output voltage of the output BGRVout exceeds the target voltage. To address this issue, the semiconductor integrated circuit 1 stops the operation and the output of the voltage division circuit 30 after the time t_{FWAKE} elapses.

The current I2 output from the scaling circuit 20 is smaller than the current I3 output from the voltage division circuit 30. However, if rise delay of the output voltage of the output BGRVout is eliminated, stable output is obtained only by the operation of the voltage source circuit 10 even when the operation of the scaling circuit 20 is stopped. Accordingly, the semiconductor integrated circuit 1 stops the operation and the output of the scaling circuit 20 at a timing at which the output voltage of the output BGRVout converges to the target voltage, that is, after the time t_{Bypass} elapses.

After the time t_{Bypass} elapses, that is, at time t3, the switch SW4 is turned off when the control signal for setting the control state Bypass is turned to be at OFF level. Accordingly, the output of the voltage source circuit 10 is smoothed by the LPF 14 and is output from the output BGRVout.

In this way, in the semiconductor integrated circuit 1 according to the first embodiment, since the scaling circuit 20 and the voltage division circuit 30 are further provided in addition to the voltage source circuit 10, the output voltage can quickly rise and quickly converge to the target voltage.

The semiconductor integrated circuit 1 according to the first embodiment transits from the first state to the fourth state in order. The first state is a state in which the scaling circuit 20 and the voltage division circuit 30 are started and the current mirror circuit 40 is not started. The second state is a state in which the scaling circuit 20 is started and the voltage division circuit 30 and the current mirror circuit 40 are not started. The third state is a state in which the current mirror circuit 40 is started and the scaling circuit 20 and the voltage division circuit 30 are not started. The fourth state is a state in which the current mirror circuit 40 is stopped and only the voltage source circuit 10 is started.

In the semiconductor integrated circuit 1 according to the first embodiment, from the first state to the third state, the output voltage of the output BGRVout quickly rises.

On the other hand, in the third state, the scaling circuit 20 and the voltage division circuit 30 are disabled (i.e., the operation is not started) and the current mirror circuit 40 is started. In the semiconductor integrated circuit 1 according to the first embodiment, in the third state, stable output can be output from the outputs BGRIout0 and BGRIout1 by the operation of the current mirror circuit 40.

Further, in the fourth state, the current mirror circuit 40 is stopped. By such an operation, constant current output can be stopped and power consumption can be reduced.

Operation according to Modification Example of First Embodiment

In the above-described first embodiment, while the outputs of the scaling circuit 20 and the voltage division circuit 30 are added to the output of the voltage source circuit 10 when the voltage source circuit 10 is started, the disclosure is not limited thereto. A configuration may be made in which only the output of the voltage division circuit 30 may be added when the voltage source circuit 10 is started. Hereinafter, a modification example where only the output of the voltage division circuit 30 is added when the voltage source circuit 10 is started will be described with reference to FIGS. 1, 8, and 9.

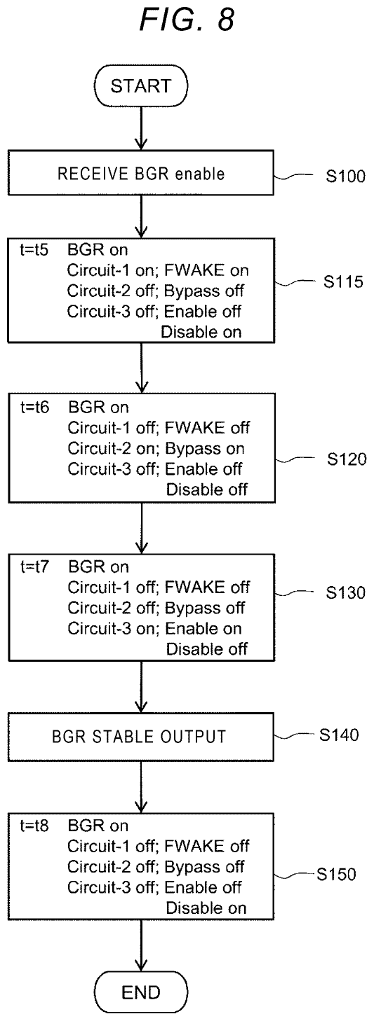

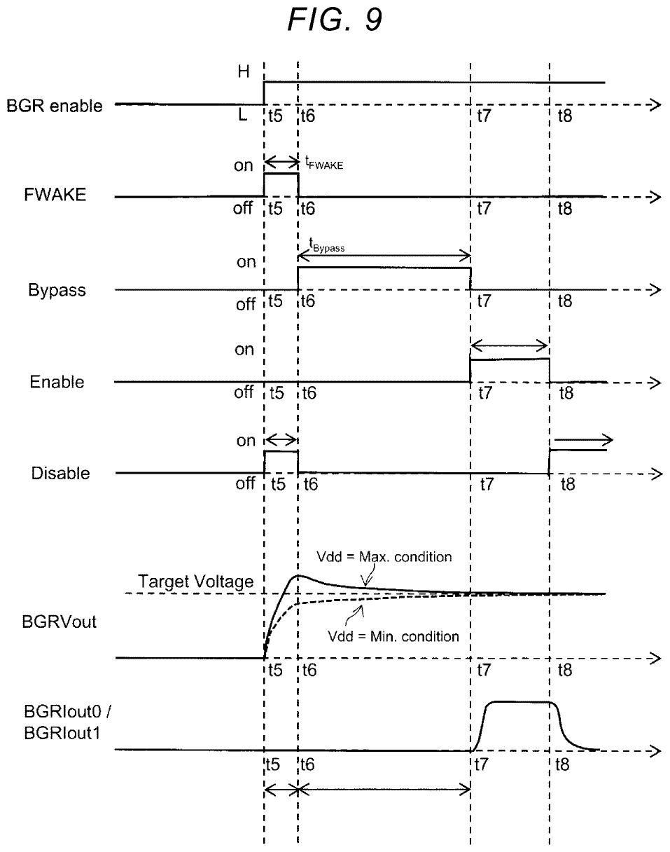

As illustrated in FIGS. 8 and 9, at time t5, upon the BGR enable signal being turned to the H level from the low level and the control circuit 50 receiving the BGR enable signal (S100), the control circuit 50 causes a control signal for setting the control state FWAKE to be at ON level, and a control signal for setting the control state Disable to be at ON level (S115). In this case, the control circuit 50 has not set the control state Bypass and the control state Enable, that is, keeps the control signals for setting the control state Bypass and the control state Enable to be at OFF levels. The voltage source circuit 10 and the voltage division circuit 30 are started, and the output voltage appears at the output BGRVout. In this case, the current I3 from the voltage division circuit 30 is added to the current I1 from the voltage source circuit 10, and flows toward the capacitor C of the LPF 14.

With this, the rise of the output voltage in a case where the voltage division circuit 30 is also started in parallel approaches the target voltage more quickly than the rise of the output voltage in a case where only the voltage source circuit 10 is started.

The current mirror circuit 40 is not started since the control signal for setting the control state Enable is at OFF level. For this reason, no current flows from the outputs BGRIout0 and BGRIout1.

Subsequently, at time t6, upon the control circuit 50 causing the control signal for setting the control state FWAKE to be at OFF level, the current I3 is not added to the current toward the capacitor C of the LPF 14. At time t6, the control circuit 50 causes a control signal for setting the control state Bypass to be at ON level and a control signal for setting the control state Disable to be at OFF level (S120). As a result, in a case where the voltage of the power supply wiring Vdd is under the maximum condition (Max), the output voltage of the output BGRVout is turned from rising to falling. That is, the output voltage falls after exceeding the target voltage by switching to the current I2 from the scaling circuit 20 that is smaller than the current I3 from the voltage division circuit 30. The time t_{FWAKE} during which the control circuit 50 keeps the control state FWAKE is set at a timing such that the output voltage of the output BGRVout falls quickly without exceeding the target voltage too much. In a case where the voltage of the power supply wiring Vdd is under the minimum condition (Min), a slope of rising of the output voltage becomes a little gentler.

Subsequently, at time t7, upon the control circuit 50 causing a control signal for setting the control state Bypass to be at OFF level, the drain voltage of the MOSFET Q5 of the voltage source circuit 10 is applied directly to the resistor R6 of the LPF 14, and a current flowing into the capacitor C of the LPF 14 becomes only the current I1. The output voltage of the output BGRVout that has quickly risen at time t5 is turned to decrease or gently rises at time t6, and converges to the target voltage at time t7. The time t_{Bypass} during which the control state Bypass is kept is set at a timing at which the output voltage converges to the target voltage. For example, the time t_{Bypass} is set to such an extent of not exceeding 50 μs.

Further, at time t7, the control circuit 50 outputs a control signal for enabling the control state Enable (S130). As illustrated in FIG. 9, at time t7, if the control signals for setting the control state Bypass and the control state FWAKE are controlled to be at OFF levels, and the control signal for setting the control state Enable is controlled to be at ON level, the current mirror circuit 40 is started, and a current is output from the outputs BGRIout0 and BGRIout1.

Subsequently, as illustrated in FIGS. 8 and 9, at time t8, the control circuit 50 causes a control signal for setting the control state Enable to be at OFF level, and a control signal for setting the control state Disable to be at ON level. The control circuit 50 keeps the control signals for setting the control state FWAKE and the control state Bypass to be at OFF levels (S150). With this, since the current mirror circuit 40 stops the operation, the current from the output BGRIout0 and the output BGRIout1 is stopped.

Also in the modification example, similar advantages to the first embodiment can be obtained.

### Second Embodiment

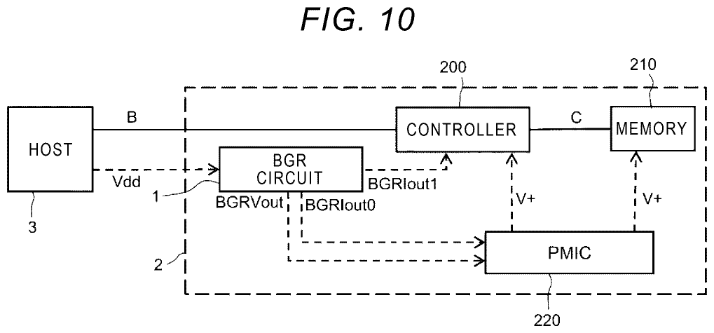

Next, an electronic apparatus according to a second embodiment will be described with reference to FIG. 10. In the following description, elements common to the first embodiment are represented by common reference signs, and duplicate description will not be repeated.

As illustrated in FIG. 10, an electronic apparatus 2 according to the second embodiment configures a memory system. The electronic apparatus 2 includes the semiconductor integrated circuit 1 serving as a BGR circuit according to the first embodiment, a controller 200, a memory 210, and a power management IC (PMIC) 220. The electronic apparatus 2 can be connected to a host 3 via a signal line B and a power supply wiring Vdd. The signal line B is a bus line that transmits and receives signals between the electronic apparatus 2 and the host 3, for example. The power supply wiring Vdd is a power supply line that can supply a prescribed voltage from the host 3 to the electronic apparatus 2, for example.

The controller 200 is a circuit element that implements functions of reading, writing, erasing, and initializing data to the memory 210 in response to a command from the host 3. The controller 200 is an electronic circuit that includes a processor to implement the above-described functions, and is configured as SoC, for example. The memory 210 is a semiconductor storage device including a NAND flash memory, for example. The memory 210 is connected to the controller 200 by a bus line including a signal line C based on a prescribed standard, for example. The controller 200 can receive supply of a current from the semiconductor integrated circuit 1 via the output BGRIout1.

The PMIC 220 is a circuit element that can generate a plurality of output voltages having different voltage values. The PMIC 220 generates various output voltages V+ in response to the output voltage of the output BGRVout and the current from the output BGRIout0 of the semiconductor integrated circuit 1, and supplies the generated output voltages V+ to the controller 200, the memory 210, and the like.

If the supply of the voltage is received via the power supply wiring Vdd, the semiconductor integrated circuit 1 serving as the BGR circuit supplies the output voltage of the output BGRVout and the current from the output BGRIout0 with a quick rise and high quality to the PMIC 220 by the operation of the first embodiment or the modification example. The PMIC 220 that receives the output voltage of the output BGRVout and the current from the output BGRIout0 generates the output voltage V+ and the like and supplies the output voltage V+ to the controller 200 or the memory 210.

With the electronic apparatus 2 according to the second embodiment, since the semiconductor integrated circuit 1 serving as the BGR circuit according to the first embodiment or the modification example is provided, high quality and high-speed start-up with respect to the power supply voltage inside the apparatus can be exhibited.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor integrated circuit comprising:
a smoothing circuit including a capacitor;
a first circuit electrically connected to the smoothing circuit and a first output terminal and configured to cause a first current to flow to the smoothing circuit, to output a first voltage to the first output terminal;
a second circuit electrically connected to the smoothing circuit and the first output terminal and configured to cause a second current to flow to the smoothing circuit, to output the first voltage to the first output terminal, the second current being greater than the first current;
a third circuit electrically connected to a second output terminal and configured to cause a third current corresponding to the first current to flow to the second output terminal; and
a control circuit configured to cause:
during a first time period, the first current and the second current to flow to the capacitor;
during a second time period subsequent to the first time period, the first current, but not the second current, to flow to the capacitor, the second time period being greater than the first time period; and
during a third time period subsequent to the second time period, the third current to flow to the second output terminal.

2. The semiconductor integrated circuit according to claim 1, wherein the control circuit is configured to cause, during the third time period, the second current to not flow to the capacitor.

3. The semiconductor integrated circuit according to claim 1, wherein the control circuit is configured to cause, during the first time period and the second time period, the third current to not flow to the second output terminal.

4. The semiconductor integrated circuit according to claim 1, wherein the first voltage output from the first circuit is more stable than the first voltage output from the second circuit.

5. The semiconductor integrated circuit according to claim 1, wherein the first circuit comprises a constant current circuit and the first current has a constant value.

6. The semiconductor integrated circuit according to claim 5, wherein the first circuit further comprises a temperature compensation circuit and the constant value is temperature compensated.

7. The semiconductor integrated circuit according to claim 1, wherein the second circuit comprises a voltage division circuit.

8. The semiconductor integrated circuit according to claim 1, wherein the third circuit comprises a current mirror circuit.

9. The semiconductor integrated circuit according to claim 1, wherein the smoothing circuit comprises a low pass filter.

10. The semiconductor integrated circuit according to claim 1, further comprising:
a fourth circuit electrically connected to the smoothing circuit and the first output terminal and configured to cause a fourth current to flow to the smoothing circuit, to output the first voltage to the first output terminal, the fourth current being greater than the first current and smaller than the second current,
wherein the control circuit is configured to, during the second time period, cause also the fourth current to flow to the capacitor.

11. The semiconductor integrated circuit according to claim 10, wherein the control circuit is configured to, during the first time period, cause also the fourth current to flow to the capacitor.

12. The semiconductor integrated circuit according to claim 10, wherein the control circuit is configured to, during the third time period, cause the fourth current to not flow to the capacitor.

13. The semiconductor integrated circuit according to claim 10, wherein the fourth circuit comprises a scaling circuit including a current mirror and the fourth current is proportional to the first current.

14. The semiconductor integrated circuit according to claim 1, wherein a voltage at the first output terminal rises during the first time period and converges to the first voltage during the third time period.

15. The semiconductor integrated circuit according to claim 14, wherein the voltage at the first output terminal exceeds the first voltage during the first time period and decreases toward the first voltage during the second time period.

16. The semiconductor integrated circuit according to claim 14, wherein the voltage at the first output terminal does not reach the first voltage during the first time period and the second time period.

17. An electronic apparatus comprising:
a memory;
a memory controller configured to control the memory; and
the semiconductor integrated circuit according to claim 1, wherein an operation voltage is generated based on the first voltage output from the first output terminal and supplied to at least one of the memory and the memory controller.

18. The electronic apparatus according to claim 17, further comprising:
a power management circuit connected to the first output terminal of the semiconductor integrated circuit, the power management circuit being configured to generate a first operation voltage based on the first voltage output from the first output terminal and supply the first operation voltage to the memory, and generate a second operation voltage based on the first voltage output from the first output terminal and supply the second operation voltage to the memory controller.

19. The electronic apparatus according to claim 18, wherein the control circuit is configured to:
cause, during the first time period and the second time period, the third current to not flow to the second output terminal; and
cause, during the third time period, the second current to not flow to the capacitor.

20. The electronic apparatus according to claim 18, wherein the semiconductor integrated circuit further comprising:
a fourth circuit electrically connected to the smoothing circuit and the first output terminal and configured to cause a fourth current to flow to the smoothing circuit, to output the first voltage to the first output terminal, the fourth current being greater than the first current and smaller than the second current,
wherein the control circuit is configured to, during the second time period, cause also the fourth current to flow to the capacitor.
